(19) United States
(12) Patent Application Publication
(10) Pub. No.: US 2020/0250357 A1
(43) Pub. Date: Aug. 6, 2020

(54) Modelling Systems and Methods for Entertainment Rides

(71) Applicant: Simworx Ltd, Kingswinford, West Midlands (GB)

(72) Inventors: Mat Stevenson, Kingswinford, West Midlands (GB); Rene Masey, Kingswinford, West Midlands (GB)

(21) Appl. No.: 16/635,075

(22) PCT Filed: Sep. 5, 2018
(86) PCT No.: PCT/GB2018/052508

§ 371 Date: Jan. 29, 2020

(30) Foreign Application Priority Data
Sep. 6, 2017 (GB) 1714289.4

(51) Int. Cl. G06F 30/15; G06K 9/00

(52) U.S. Cl. CPC G06F 30/15; G06K 9/00711; G06K 9/00791

(57) ABSTRACT

A method of modelling the motion base of a vehicle in an entertainment environment having a display, the method comprising receiving visual media data to be displayed in the entertainment environment; determining a motion map from the visual media, said motion map indicative of the movement of a camera in the visual media data; normalising the motion map to the motion base of the vehicle; identifying a first cue in the visual media data and said cue determining a time for said cue, wherein the determination is based on time code data stored in the media data; identifying in the motion map a plurality of instances of the cues and synchronising the motion map with the plurality of instances of the cues based on the determined time for said cue.

### FIELD OF THE INVENTION

The present invention relates to a modelling system for modelling the movement of vehicles such as an automated guided vehicle, such as those used in amusement rides. Particularly, but not exclusively, the disclosure relates to the modelling of such vehicles in an entertainment environment with synchronised audio and video elements.

### BACKGROUND TO THE INVENTION

Automated Guided Vehicles (AGVs) are known in entertainment and attractions industry. In particular such vehicles provide a dynamic movement within a confined space in a trackless environment. Theme park rides typically utilise passenger carrying AGVs to provide an immersive entertainment experience. The AGV moves through a themed environment and its movements are synchronised with elements of the themed environment. Such elements may include, for example, scenery, props, animatronics, audio effects, visual effects, pyrotechnic effects and olfactory effects. So as to provide maximum passenger enjoyment, the movement of the AGV is synchronised very closely with the themed environment elements.

Furthermore, when designing such environments passenger safety and end user safety is of paramount importance.

In the entertainment and attractions industry typically the visual and audio effects (in the form of a movie) are supplied and the vehicle—such as the AGV— is programmed to move in the environment and to synchronous its motion with the audio visual cues. For example where the movie displays a particular type of event, for example a collision, the motion of the vehicle is such that to replicate a collision type event. Due to the complexities of the motion the accurate synchronisation of the motion of the vehicle with the audio visual film is non-trivial. In known systems this is typically performed manually which is time consuming as the vehicle must be ridden and chances are tested manually. Accordingly, any changes are made in an iterative time consuming fashion.

### SUMMARY OF THE INVENTION

Aspects and embodiments of the invention provide a method claimed in the appended claims

Accordingly in order to address some of the above issues there is provided a method of modelling the motion base of a vehicle in an entertainment environment having a display, the method comprising receiving visual media data to be displayed in the entertainment environment; determining a motion map from the visual media, said motion map indicative of the movement of a camera in the visual media data; normalising the motion map to the motion base of the vehicle; identifying a first cue in the visual media data and said cue determining a time for said cue, wherein the determination is based on time code data stored in the media data; identifying in the motion map a plurality of instances of the cues and synchronising the motion map with the plurality of instances of the cues based on the determined time for said cue.

Thus the method provides an improved modelling system which ensures that the motion of the vehicle is synchronised with the visual data thus improving any end user's experience. The methodology uses a simulation based motion profile generator, incorporating both a physics engine (to examine and report on dynamic motion violations), and a spatial and velocity validation tool (operating in either 2D or 3D to report on spatial safety violations), thereby providing proof cases from within the simulation environment of any positional, dynamic motion and safety related violations generated by the simulation output.

Correspondingly, the solution is also able to input a programme previously generated by a ride control system or a solution provided by 3rd party data and similarly provide analysis and proofs.

Optionally, the motion map is calculated for each of a plurality of degrees of freedom associated with the vehicle. Thus providing a more accurate map.

Optionally further comprising the step of determining a physical parameter of motion of the vehicle via a physics engine. Preferably 3 wherein the physical parameter is one or more of jerk, torque, acceleration. Beneficially it is possible to determine the forces that would be experienced during the testing phase thus saving time and money.

Optionally further comprising displaying the motion map and video data thus allowing for a representation of the likely ride experience. Optionally further comprising editing the motion map for one or more of the calculated degrees of freedom of the vehicle beneficially allowing for improved modelling.

Optionally further comprising adding a first predetermined movement to the motion map. By predetermining set motions known, safe, motions can be readily added to the motion map in an efficient manner.

Optionally wherein the step of normalising the motion map to the motion base of the vehicle comprises for a first degree of freedom of the vehicle determining the physical limit of the vehicle for said degree of freedom and scaling the motion to the physical limits of the vehicle. Beneficially this ensures that the vehicle is not subjected to forces or movements outside its safe limits.

Optionally further comprising the step of determining the physical forces experienced by a passenger in the vehicle and/or the vehicle as a result of the motion of the vehicle. Preferably further comprising the steps of identifying any instances of the physical force experienced being greater than a predetermined limit. Preferably further comprising the step of generating a report describing the forces and motion plan against the predetermined limits. Preferably wherein the forces are selected from the group of velocity, acceleration, torque, g-force, acceleration, deceleration. Such features ensure that the motion map determined is safe for any human to ride on. Such safety is important within the entertainment industry.

As such the invention provides an improved system in which motion of a vehicle can be determined in order to provide an improved entertainment design environment. In particular the system enables ride designers to ensure that the motion of a vehicle is synchronised with the video data and furthermore ensure that the motion of the vehicle is within the safe operating limits of the vehicle and is also safe for the riders.

### BRIEF DESCRIPTION OF FIGURES

FIG. 1 is a schematic of an entertainment ride system which is found in the prior art;

FIG. 2 is a flow chart of the process according to an aspect of the invention;

FIG. 3 is a representation of the rendering a graphical representation of the motion map data and video data;

FIG. 4 is an example of content and motion map of a vehicle in an embodiment of the invention; and

FIG. 5 is a work flow according to an embodiment of the invention.

### DETAILED DESCRIPTION

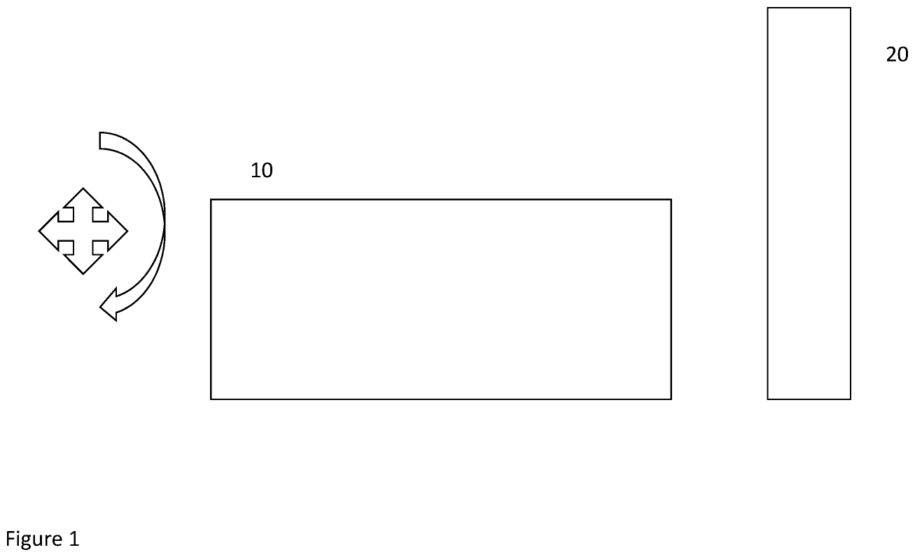

FIG. 1 is a schematic of an entertainment ride system which is found in the prior art.

There is shown a vehicle 10 in which one or more users of the ride sit. The vehicle 10 is of a known type, for example an automated guided vehicle (AGV). The vehicles typically have between three to six degrees of freedom, with the vehicle 10 having a plurality of articulated wheels allowing the vehicle to move within an environment. Furthermore a vehicle will typically have a number of actuators, or other means such as robotic arms, which cause the cabin or seats in which are user is placed to move. Such vehicles 10 are known in the art and examples of such vehicles are described in WO2014191720.

There is also shown a display 20 on which visual content is shown. Such displays may be projected or immersive and are known in the art. As is known in order to enhance the user experience it is desirable to synchronise the motion of the vehicle 10 with the content shown on the display 20. For example if the content shown on the display 20 is a driving experience, then it is desirable to move the vehicle 10 to provide the user with the effect of driving. For example if the display 20 shows a car cornering then the vehicle 10 may be moved across its various axis to replicate the effect, similarly if the display 20 shows a sudden acceleration, or deceleration, of a car then the vehicle 10 is moved in such a manner to replicate the acceleration or deceleration.

The programming of the movement of the vehicle 10 to synchronise with the content of the display 20 is non-trivial and time consuming. The present invention aims to provide an improved modelling system to enable a designer to program the movement of the vehicle 10 across all of its available degrees of freedom in a manner which synchronises with the displayed content.

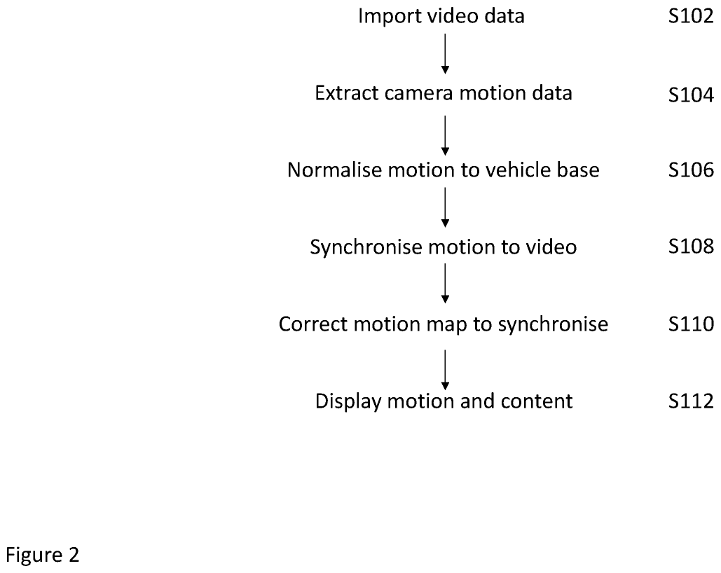

FIG. 2 is a flow chart of the process according to an aspect of the invention.

The invention provides a system to allow a designer of an entertainment ride to receive a video file, which contains the visual effects that are presented to a rider/end user of a ride, and produce a motion map which describes the motion the vehicle would take during the ride. The programming of the vehicle's motion to coincide with the video data is a key consideration when programming vehicle motion via the motion map.

At step S102 video data is imported into the system.

In the entertainment ride industry, a ride is typically commissioned by a company who will create a cinematic experience for a user to experience. For example, the experience may be a driving experience with the ride designed to replicate in part, the experience of driving a particular route. Typically a company, for example an animation studio, will create a video which is to be projected to the users of the ride and instruct a company to create the motion base required to enhance the user experience by replicating the motion experience. The video data is in the known format for animated data with data describing the content to be rendered and data describing the motion of the camera.

At step S104 the motion data of the camera is extracted from the video data.

The motion data of the camera defines the extent of the movement shown in the content. For example if the video data shows a roller coaster ride (as seen from the perspective of a passenger sat on the roller coaster) the motion data might define that in the z-axis there is a motion of +−50 metres, and that there is a pitch of +−30 degrees. Other motion data regarding other degrees of freedom are also extracted.

As is known in the art, video animation data will contain data describing the location and motion of the camera through an environment. Such data is extracted at step S104.

At step S106 the extracted motion data is normalised to the vehicle base for which the motion is being modelled.

The present invention provides the ability to model the motion of a vehicle within the entertainment environment. Depending on the ride different vehicle bases are used. For example for a first ride automated guided vehicles are used and for a second ride robotic actuated arms are used. The present invention is designed to provide sufficient flexibility to allow for the programming of the motion for different types of vehicle.

Each vehicle will have limits to the range of motions it can perform. Such limits may be physical limitations (for example a limit imposed by the size and shape of the vehicle, the actuators etc.) or safety based (for example for certain types of vehicle it may be undesirable to move the vehicle beyond a certain angle as there would be a risk that a user may fall out, or for rides aimed at children then certain motions may be undesirable). The constraints therefore would change according to the user and vehicle to be modelled.

For example constraints of a vehicle may be the ride height may be varied by +−10 cm, the pitch by +−15 degrees, the yaw by +−15 degrees, the maximum rate of change may be 5 degrees per second. Furthermore, two of more constraints may be combined to define a further limitation, for example due to the physical size of the cabin when the pitch is over 10 degrees the yaw may only be a maximum of +−7 degrees.

Thus the physical limitations of the vehicle are typically much less than the motion of the camera. In the rollercoaster example the change in height (i.e. z axis) might be 100 metres with the vehicle only able to adjust its height by 20 cm. As such there is a significant variation in the amount of movement that is possible and the camera motion data.

Furthermore the difference between the desired motion and allowed motion will vary for each degree of freedom, sometimes by several orders of magnitude. Accordingly for each degree of freedom the camera motion data is normalised to the limits of the motion of the vehicle at step S106.

The normalisation can occur in a number of known manners. For example in embodiments where the range of movement of the camera motion data is within a tolerance of the maximum capabilities of the machine, for example within 120% then the camera motion data is simply scaled to match the range of allowed motions of the vehicle.

In further embodiments where the variation in camera motion data is much greater than the limits of the vehicle the normalisation, or correction, is defined such that the user experiences the rate of change of value rather than the absolute values, so as to provide the appropriate motion experience. For example, in the roller coaster example, when a carriage climbs to the top of a feature it may be so along a constant incline and as such the rate of change of height would increase at the start of the incline and remain constant for the remainder of the incline. To simulate the effect of the change in height to the user, the changes in the rate of change are used and normalised to the vehicle's physical limitations. In such a manner, in the rollercoaster example, the user when sat in the vehicle, would experience a motion at the bottom of the incline (to provide the sensation of the vehicle commencing the climb up the incline) and this sensation would diminish over time (by the vehicle returning to an equilibrium value) whilst the rate of change of height remains constant. Such corrections may be applied by utilising preprogramed models to normalise motion to the limits of a vehicle.

Preferably at step S106 the motion data is calculated for each degree of freedom of the vehicle individually. Furthermore, other physical parameters, such as jerk, torque, acceleration etc., are calculated at step S106. The calculation for each force is calculated for the vehicle and any passenger in the vehicle. For each degree of freedom and physical parameter the value of the degree of freedom or parameter is determined over time. Preferably this is presented in a graph form, though other forms of presenting the data may be used.

The physical parameters are calculated using known physics engines which can calculate the physical form experienced due to the motion. Such physics engines are known in the art.

Advantageously at step S106 the normalised motion data, and the determined physical forces experienced by both the vehicle and passengers, can be validated to ensure safe operation. The limits are predetermined and may be varied according to the type of vehicle and passenger (adult, child, toddler etc.). As the information is presented in a graphical format, in a preferred embodiment each of the forces can presented visually as a “go-no go” validation. Preferably a report of the motion plan detailing the forces experienced is generated, and/or a traffic light output of the forces (and the motion plan) is generated against pre-set approval limits. Therefore it is possible to quickly identify instances where a passenger and/or vehicle may experience high, or dangerous, forces and allow the motion base to be amended accordingly. Preferably where the forces experienced by a passenger and/or the vehicle are greater than a predetermined limit the system presents an error message and prevents the process from continuing until such time that the motion is changed and the forces experienced are within a safe limit.

The forces or parameters which care monitored include number of passengers, vehicle kinematic arrangement, maximum velocity, torque, g forces, acceleration and deceleration, pose, positions, illegal spatial positions and orientations. Thus at step S106 ensures that the motions and forces experienced are within safe operating limits.

Thus at step S106 a motion map for the vehicle base is defined, said motion map being normalised to the limits of the vehicle.

At step S108 the motion data extracts at step S104 is synchronised with the normalised vehicle motion data as calculated at step S106.

In entertainment rides the synchronisation of the vehicle motion with the displayed content is an important factor in ensuring user enjoyment and experience. Furthermore, when the motion of the vehicle and the displayed video content does not coincide it may cause the user to experience motion sickness.

In animation data (as imported at step S102) timecodes are used to define each frame of data. Typically the timecodes comply with SMPTE timecode standard.

At step S108 the video data is analysed and a number of cues are identified.

The cues may be visual and relate to an event occurring in the video, or physical. In the rollercoaster example a visual cue may be a sequence to show that the ride is about to start. A physical cue may be a particular motion, for example the start of an incline etc. In other examples, a cue may be both physical and visual. For example in the rollercoaster example a particular feature of the rollercoaster (such as a corkscrew type motion) the physical motion has a visual component associated therewith. The nature of the cues therefore varies according to the ride type and the content shown. As would be apparent to the skilled person the nature of the cue is defined by the video/animation. As described above, in the entertainment ride industry the ride is typically programmed to fit the visual animation/video data. As such the determination of the cues will be made from video data.

At step S108 for the identified cues the timecode associated with the cue is identified.

At step S110 the motion map data as determined at step S106 is synchronised with the timecodes for the visual cues. Thus the motion map for the vehicle is corrected to ensure that the define motion corresponds with the content of the video.

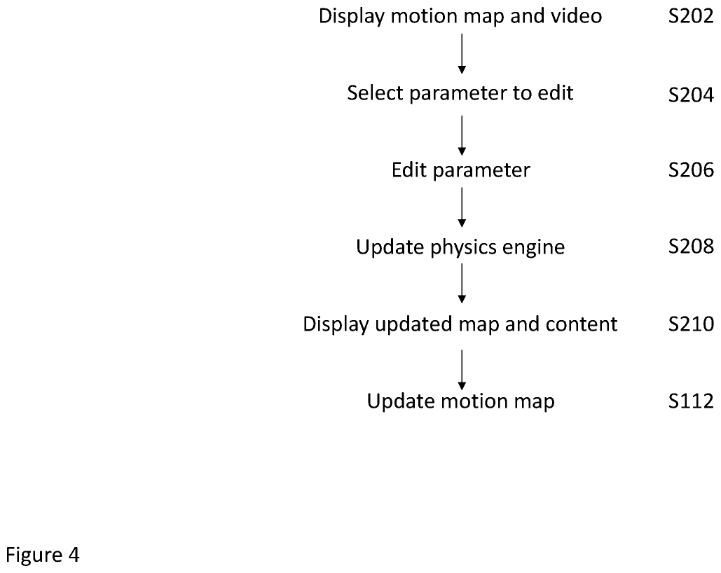

At step S112 the video content and corresponding motion map of the vehicle is rendered on a screen. An example of content and motion map of the vehicle is shown in FIG. 4.

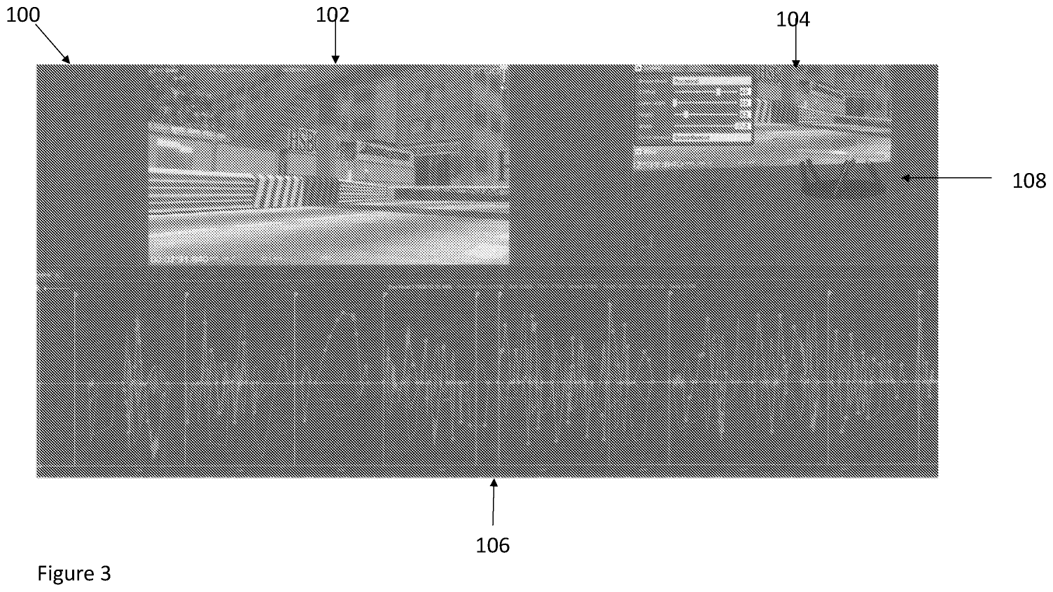

In FIG. 3 there is shown a representation of the rendering a graphical representation of the motion map data and video data.

There is shown the display 100, the display 100 comprising a first screen 102 and a second screen 104. There is also shown the corresponding motion map data 106 for the vehicle 108. As described above the motion map is calculated for each degree of freedom of the vehicle as well as other physical parameters of interest. As shown in

FIG. 4 the graph of the value for a particular parameter of the motion map (i.e. degree of freedom or physical parameter) is plotted. Thus as the first and second displays show the video and the motion of the vehicle there is also shown the variation of the value over time.

The first screen 102 shows the video data as imported into the system at step S102. Thus the programmer is provided with a clear view of the content to be displayed to the ride users. The first screen 102 also therefore enables the ride programmer to check that the motion of the vehicle matches that of the video.

The second screen 104 shows a representation of the vehicle and the screen on which the video data is projected. The motion of the vehicle 108 is shown in the second display as well as the content, therefore it can be checked whether the vehicle 108 motion synchronises with the displayed content on the first and second screens. The content of the first 102 and second 104 screens is synchronised.

Furthermore, the graph based representations of the individual degrees of freedom and/or physical parameters of the vehicle as calculated by the physics engine are displayed 106. The content of the screen 102 104 and graphs 106 are also synchronised such that at a given point the data presented in the graph form is the data for that particular point in time.

Thus at step S112 the program allows a vehicle ride programmer to view the planned motion of the vehicle and how it corresponds with the video data.

The above process therefore allows a programmer to make an initial attempt at programming the vehicle motion such that it synchronises with the video data. Advantageously the present invention allows for the programmer to view and amend the motion for each degree of freedom as well as physical parameter in order to provide the best end user experience. Furthermore, by having the detailed information at the programming stage it is possible for the programmer to determine likely wear on the vehicle which provides advantages in terms for determining the need for servicing and repair for a vehicle.

Further advantages are that by providing, and calculating, the physical forces experienced by the vehicle rider comfort and safety can be improved. By calculating and visualising the various forces potentially uncomfortable or dangerous motions are more readily identifiable and can be accounted for.

A further aspect of the invention is that in addition to calculating the gross motion of the vehicle based on the camera data, the invention allows for the fine tuning of the motion and the addition of further fine motion to enhance the ride experience.

FIG. 4 is a flow chart of the process of amending the motion map as generated at FIG. 2.

The process in FIG. 4 can be performed as part of the same process as FIG. 2 or can be performed separately.

At step S202 the motion map and video data is displayed on a display. The process is as per step S112.

At step S204 the user selects one or more of the degrees of freedom or physical parameters to edit.

The selection occurs using known selection means, such as tick boxes, drop down menus etc.

The parameter to be edited is subsequently displayed in graph form showing the value of the parameter and its variation over time.

At step S206 the user edits the motion map by editing the value of the degree of freedom or parameter. As is known in the art, the programming of the motion of a vehicle is often varied, or tweaked. Such variations may be to add, or remove, motion so as to enhance the rider's experience. The editing of the motion map therefore provides the programmer with the ability to vary the motion map (and therefore motion of the vehicle) in order to provide optimal user experience.

At step S206 the ride programmer is able to select a physical parameter (e.g. acceleration) and edit that parameter, thereby affecting the motion of the vehicle.

In some embodiments in order to edit a parameter the user is able to select and apply one or more filters to one or more parameters to change the motion. For example the acceleration experienced by a passenger can be increased or decreased according to the needs. Such filters are known in the art. In further embodiments as the values are shown in a graph form, the user is able to select one or more points of the graph and vary the selected points to the desired values. In further embodiments other forms of selection and editing are used.

In further embodiments one more set motions may be added into the motion map. A set motion would be one that is typically repeated in the same ride, or in different rides, to provide a known sensation to a user. For example, in a driving ride, a set motion may be a particular type of turn such as a j turn, a collision event, a skidding motion etc. By programming the set motions required to replicate such an effect, the set motion can be imported into the motion map. As the motions are set i.e. predetermined, time is saved when using such motions as the parameters have already been determined.

Advantageously, by separating the effect of each degree of freedom and the physical parameter the programmer can finely adjust and control the motion of the vehicle base. Each parameter and degree of freedom can be edited separately providing the ride programmer with a high degree of fine control. For example, in the rollercoaster example further fine motion can be added to the gross motion of the vehicle to provide an improved user experience. In the example discussed above of the rollercoaster slowly climbing an incline whilst the gross motor effect of the climbing motion is modelled (as per step S106) further effects can be included on top of the normalised motor. For example additional motion in the z-axis and y-axis may be added to replicate a juddering motion. Such extra effects are added at step S206.

As such the editing process allows for further effects to be added on top of the normalised motion of step S106 which replicates the gross camera motion.

Furthermore, any changes made in the editing process result in the physics engine calculating the forces experienced by the end user at step S208. Thus for each and every change made the forces experienced by the user are known. As is known the need for rider/end user safety is paramount and the forces that the end user experiences must be known to ensure that the ride does not exert any dangerous forces onto a user. Preferably where an edit of the motion map results in the physics engine determining that the forces that a user would experience would approach or exceed a predefined safety limit a warning is presented and/or the program prevents the edit from being made.

At step S210 the changes to the motion map are checked by the programmer by viewing the changes with the video data as described with reference to FIG. 2.

At step S212 the vehicle motion map is updated with the edited data.

As such the invention provides the programmer with the ability to review all changes to ensure that the changes made are consistent with the video to which it is synchronised.

When the programmer has completed the process the vehicles are programmed with the motion map data to move in the programmed manner, such that the movement of the vehicle is therefore synchronised with the video.

The present invention therefore allows the changes to the programming of the motion of the vehicle in the ride to be made in a fast, consistent manner with the programmer having a full knowledge of how the changes made will affect the motion and forces experienced by the vehicle. Furthermore, by calculating the forces etc., before any changes are implemented within a ride, the system allows for a fully auditable and certifiable system in which a riders experience and safety are improved.

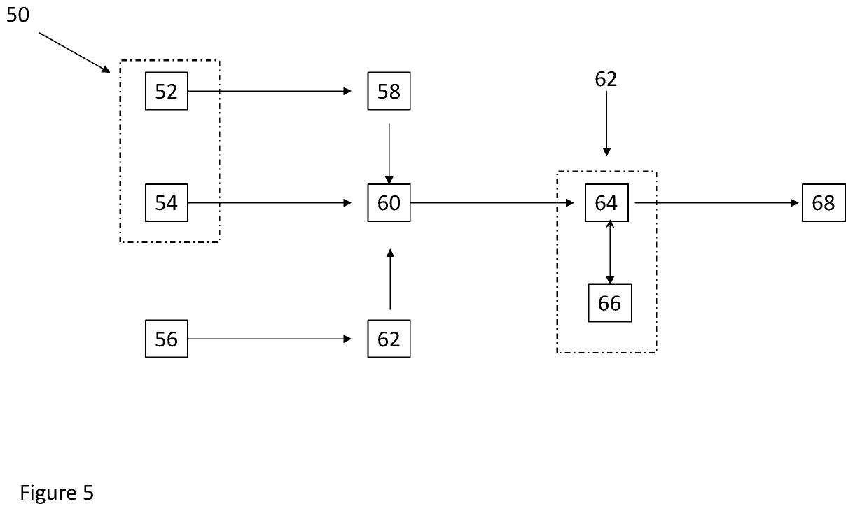

FIG. 5 is a work flow of the present invention.

In FIG. 5 there is shown the workflow process which implements an embodiment of the present invention.

There is shown a media module 50, comprising media camera data 52 and media 54. The camera data 52 in an embodiment is in 3DS Max/Maya format. The camera data 52 describes the motion of the camera in the media 54. The media 54 is the audiovisual content. There is also shown the selection of the platform 56. Examples of platforms include Stewart motion base (6DoF), 3DoF motion base, AGV, robotic arm, AGVs with motion base, AGV with robotic arm.

In an embodiment the media camera data 52 is passed to a wash out filter consisting of high and low pass filters 58 to remove any noise and to maintain the gross camera motion. The data from the filter 58 is sent to the motion project module 60. The motion project module defines the motion map as described above. Furthermore, the media 54 is imported directly into the motion project module 60. The selected platform 56 is imported 62 into the motion project module 60 thereby defining the vehicle, or platform, for which the motion is to be modelled.

From the imported data the motion project module 60 defines the motion map for the vehicle based on the imported camera data 52 which has been corrected by the wash out filter 58 and normalised as described with reference to FIG. 2.

The motion project module 60 passes the motion map to the edit/create module 62. The edit/create module comprises a review 64 and analyse 66 loop. The review process 62 occurs as described with reference to FIGS. 3 and 4 where the changes are displayed to the programmer and checked for compatibility with the motion base. The analyse module 66 calculates using a physics engine the forces experienced by the vehicle and users of the ride for safety purposes.

Once the process is complete the finalised motion map is exported to the motion platform 68 such that the vehicle is programmed with the motion map.

Further advantages of the system are that as the forces exerted on the passengers and vehicle are known it is possible to determine the likely wear on the vehicle. Such information is calculated, in an embodiment by integrating the force experienced over the course of ride. Therefore the entire force experienced by the vehicle over the course of a ride is known. Such knowledge is useful in determining the likely life cycle of a vehicle before parts need replacing. Furthermore, knowledge of the forces experienced by the user can be used to determine the likelihood of a user to experience motion sickness. As such motions which are likely to cause motion sickness can be identified and the motion of the vehicle changed accordingly.

1. A method of modelling the motion base of a vehicle in an entertainment environment having a display, the method comprising
receiving visual media data to be displayed in the entertainment environment;
determining a motion map from the visual media, said motion map indicative of the movement of a camera in the visual media data;
normalising the motion map to the motion base of the vehicle;
identifying a first cue in the visual media data and said cue determining a time for said cue, wherein the determination is based on time code data stored in the media data;
identifying in the motion map a plurality of instances of the cues and synchronising the motion map with the plurality of instances of the cues based on the determined time for said cue.

2. The method of claim 1 wherein the motion map is calculated for each of a plurality of degrees of freedom associated with the vehicle.

3. The method of claim 1 further comprising the step of determining a physical parameter of motion of the vehicle via a physics engine.

4. The method of claim 3 wherein the physical parameter is one or more of jerk, torque, acceleration.

5. The method of claim 1 further comprising displaying the motion map and video data.

6. The method of claim 2 further comprising editing the motion map for one or more of the calculated degrees of freedom of the vehicle.

7. The method of claim 1 further comprising adding a first predetermined movement to the motion map.

8. The method of claim 1 wherein the step of normalising the motion map to the motion base of the vehicle comprises for a first degree of freedom of the vehicle determining the physical limit of the vehicle for said degree of freedom and scaling the motion to the physical limits of the vehicle.

9. The method of claim 1 further comprising the step of determining the physical forces experienced by a passenger in the vehicle and/or the vehicle as a result of the motion of the vehicle.

10. The method of claim 9 further comprising the steps of identifying any instances of the physical force experienced being greater than a predetermined limit.

11. The method of claim 10 further comprising the step of generating a report describing the forces and motion plan against the predetermined limits.

12. The method of claim 9 wherein the forces are selected from the group of velocity, acceleration, torque, g-force, acceleration, and deceleration.

13. A system for modelling the motion base of a vehicle in an entertainment environment having a display, the system comprising a computing device configured to perform the steps of: receiving visual media data to be displayed in the entertainment environment
determining a motion map from the visual media, said motion map indicative of the movement of a camera in the visual media data;
normalising the motion map to the motion base of the vehicle;
identifying a first cue in the visual media data and said cue determining a time for said cue, wherein the determination is based on time code data stored in the media data;
identifying in the motion map a plurality of instances of the cues and synchronising the motion map with the plurality of instances of the cues based on the determined time for said cue.

14. A computer readable medium, which when executed by a processor cause the processor to execute the steps of: receiving visual media data to be displayed in the entertainment environment;
determining a motion map from the visual media, said motion map indicative of the movement of a camera in the visual media data;
normalising the motion map to the motion base of the vehicle;
identifying a first cue in the visual media data and said cue determining a time for said cue, wherein the determination is based on time code data stored in the media data;
identifying in the motion map a plurality of instances of the cues and synchronising the motion map with the plurality of instances of the cues based on the determined time for said cue.
